(19) United States
(12) Patent Application Publication
(10) Pub. No.: US 2025/0275432 A1
(43) Pub. Date: Aug. 28, 2025

(54) DISPLAY DEVICE

(71) Applicant: LG Display Co., Ltd., Seoul (KR)

(72) Inventors: JongHwae LEE, Seongnam-si (KR); KyoungJin PARK, Paju-si (KR); Hyein PARK, Gwangju (KR)

(73) Assignee: LG Display Co., Ltd., Seoul (KR)

(21) Appl. No.: 19/020,734

(22) Filed: Jan. 14, 2025

(30) Foreign Application Priority Data
Feb. 27, 2024 (KR) 10-2024-0028091

(51) Int. Cl. H10K 59/80

(52) U.S. Cl. CPC H10K 59/873

(57) ABSTRACT

A display device can include a first substrate divided into a display area and a non-display area, a second substrate disposed on the first substrate, and a dam provided in the non-display area, disposed between the first substrate and the second substrate, and configured to bond the first substrate and the second substrate. The non-display area includes a first area and a second area. Further, a first gap between the first substrate and the second substrate in the first area of the non-display area is larger than a second gap between the first substrate and the second substrate in the second area of the non-display area.

### CROSS-REFERENCE TO RELATED APPLICATIONS

This application claims priority to Korean Patent Application No. 10-2024-0028091 filed on Feb. 27, 2024, in the Korean Intellectual Property Office, the entire contents of which is hereby expressly incorporated by reference into the present application.

### BACKGROUND

### Field

The present disclosure relates to a display device, and more particularly, to a display device with a reduced bezel width.

### Discussion of the Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

As the representative display devices, there are a liquid crystal display (LCD) device, an electrowetting display (EWD) device, an organic light-emitting display (OLED) device, a micro OLED device, and the like.

Among the display devices, an organic light-emitting display device can be known as a display device that autonomously emits light. Unlike a liquid crystal display apparatus, the organic light-emitting display device does not require a separate light source such as a backlight unit. Thus, the organic light-emitting display device can be manufactured as a lightweight, thin display device.

In addition, the organic light-emitting display device is advantageous in terms of power consumption since the electroluminescent display device operates at a low voltage.

Further, the organic light-emitting display device is expected to be adopted in various fields because the organic light-emitting display device is also excellent in implementation of colors, response speeds, viewing angles, and contrast ratios (CRs).

Among various improvements, there is a need to provide a display device having a reduced bezel width, so that the non-display area of the display device can be reduced or minimized, which improves the design of the display device.

Further, there is a need to provide a display device with improved bonding properties for the substrates.

### SUMMARY OF THE DISCLOSURE

An object to be achieved by aspects of the present disclosure is to provide a display device in which a width of a non-display area, which can be a bezel area, is reduced.

Another object to be achieved by aspects of the present disclosure is to provide a display device where a suppression of moisture penetration can be improved or maximized even in a case where a non-display area is reduced.

Another object to be achieved by aspects of the present disclosure is to provide a display device having an increased bonding surface area in a non-display area, which can improve a bonding property of the substrates in the display area.

Objects of the present disclosure are not limited to the above-mentioned objects, and other objects, which are not mentioned above, can be clearly understood by those skilled in the art from the following descriptions.

In order to achieve the above-mentioned objects, one aspect of the present disclosure provides a display device including a first substrate divided into a display area and a non-display area, a second substrate disposed on the first substrate and a dam provided in the non-display area, disposed between the first substrate and the second substrate, and configured to bond the first substrate and the second substrate, in which the non-display area includes a first area and a second area, and in which a first gap between the first substrate and the second substrate in the first area is larger than a second gap between the first substrate and the second substrate in the second area.

Another aspect of the present disclosure provides a display device including a first substrate divided into a display area and a non-display area, a second substrate disposed on the first substrate and a dam provided in the non-display area, disposed between the first substrate and the second substrate, and configured to bond the first substrate and the second substrate, in which the non-display area includes a first area and a second area, in which at least one of the first substrate and the second substrate in the first area includes a modified portion provided on an inner surface thereof, in which at least one of the first substrate and the second substrate in the second area includes a non-modified portion provided on an inner surface thereof, and in which the modified portion has higher surface roughness than the non-modified portion.

Other detailed matters of the example embodiments are included in the detailed description and the drawings.

According to aspects of the present disclosure, it is possible to decrease the width of the bezel and increase the moisture penetration distance.

According to aspects of the present disclosure, the substrate can be etched, and the dam can be positioned at the etched position, such that a sufficiently reliable moisture penetration distance can be defined and provided even though the width of the bezel is reduced.

According to aspects of the present disclosure, the physical or chemical surface treatment can be performed on the portion of the substrate disposed in the non-display area, such that a sufficiently reliable moisture penetration distance can be defined and provided even though the width of the bezel is reduced.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a top plan view of a display device according to a first embodiment of the present disclosure;

FIG. 2 is a cross-sectional view of a subpixel of the display device according to the first embodiment of the present disclosure;

FIG. 3 is a cross-sectional view taken along line I-I′ in FIG. 1;

FIG. 4 is a cross-sectional view of a display device according to a second embodiment of the present disclosure;

FIG. 5 is a cross-sectional view of a display device according to a third embodiment of the present disclosure;

FIG. 6 is a cross-sectional view of a display device according to a fourth embodiment of the present disclosure;

FIG. 7 is a cross-sectional view of a display device according to a fifth embodiment of the

present disclosure; and

FIG. 8 is a cross-sectional view of a display device according to a sixth embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure.

Further, in the following description of the present disclosure, a detailed explanation of known related technologies can be omitted to avoid unnecessarily obscuring the subject matter of the present disclosure. The terms such as “comprising,” “including,” “having,” etc. used herein are generally intended to allow other components to be added unless the terms are used with the term “only”. Any references to singular can include plural unless expressly stated otherwise. Further, the term “can” fully encompasses all the meanings and coverages of the term “may.”

Components are interpreted to include an ordinary error range even if not expressly stated.

When the position relation between two parts is described using the terms such as “on”, “over,” “above”, “below”, “under”, “below,” “next”, etc., one or more parts can be positioned between the two parts unless the terms are used with the term “immediately” or “directly”.

When an element or layer is disposed “on,” “over,” or “above” another element or layer, another layer or or other layers or elements can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. For instance, any feature discussed herein in connection with any embodiment or example may be applied to any display device discussed herein in connection with any other embodiment or example.

Hereinafter, various embodiments of the present disclosure will be described in detail with reference to the drawings. All the components of each display device according to all embodiments of the present disclosure are operatively coupled and configured.

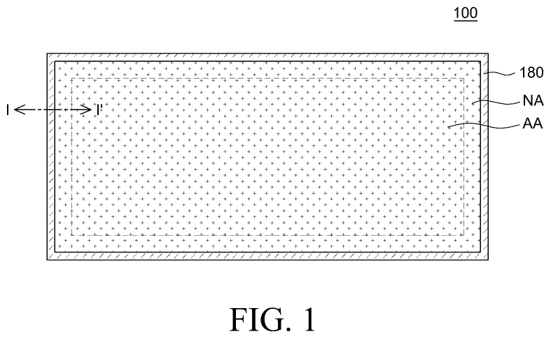

FIG. 1 is a top plan view of a display device according to a first embodiment of the present disclosure.

With reference to FIG. 1, the display device of the first embodiment of the present disclosure can include a display panel 100. The display panel 100 is a panel configured to display images to a user.

The display panel 100 can include a plurality of display elements configured to display images, a plurality of driving elements configured to operate the display elements, and lines configured to transmit various types of signals to the display elements and the driving elements.

Different display elements can be defined depending on the types of display panels 100. For example, in a case where the display panel 100 is an organic light-emitting display panel, the display element can be an organic light-emitting element including an anode, an organic light-emitting layer, and a cathode.

In another example, in a case where the display panel 100 is a liquid crystal display panel, the display element can be a liquid crystal display element.

Hereinafter, an assumption is made that the display panel 100 is an organic light-emitting display panel. However, the display panel 100 is not limited to the organic light-emitting display panel and can be of a different type.

The display panel 100 can include a display area (or active area) AA and a non-display area (or non-active area) NA.

The display area AA is an area of the display panel 100 in which images are displayed.

The display area AA can include a plurality of subpixels configured to constitute a plurality of pixels, and one or more circuits configured to operate the plurality of subpixels. The plurality of subpixels are minimum units that constitute the display area AA.

The display element mentioned above can be disposed in each of the plurality of subpixels. The plurality (or group) of subpixels can constitute each pixel. For example, each of the plurality of subpixels can include the light-emitting element (e.g., organic light-emitting element) including the anode, the light-emitting layer, and the cathode. However, the present disclosure is not limited thereto.

In addition, the circuit configured to operate the plurality of subpixels can include driving elements, lines, and the like. For example, the circuit can include a thin-film transistor, a storage capacitor, a gate line, a data line, and the like. However, the present disclosure is not limited thereto.

The non-display area NA included in the display panel 100 is an area in which no image is displayed.

The non-display area NA can surround entirely the display area AA having a quadrangular shape. However, the shapes and arrangements of the display area AA, the non-display area NA and the display panel 100 are not limited to the example illustrated in FIG. 1.

In other words, the shape and/or arrangement of the display area AA and the non-display area NA can be suitable set for a design of an electronic device equipped with the display device. For example, an example shape of the display area AA can also be a pentagonal shape, a hexagonal shape, a circular shape, an elliptical shape, or the like.

Various lines and circuits for operating the organic light-emitting element in the display area AA can be disposed in the non-display area NA. For example, the non-display area NA can include link lines for transmitting signals to the plurality of subpixels and the circuits in the display area AA. The non-display area NA can include a drive integrated circuit (IC) such as a gate driver IC and a data driver IC. However, the present disclosure is not limited thereto.

The gate driver IC can generate and provide gate signals to the pixels of the display panel 100, and the data driver IC can generate and provide data signals to the pixels of the display panel 100.

The display device can include various additional elements configured to generate various signals or operate the pixel in the display area AA. The additional elements for operating the pixel(s) can include an inverter circuit, a multiplexer, an electrostatic discharge (ESD) circuit, and the like.

For example, the display device can include a timing controller, a power supply, etc. in addition to the gate driver and the data driver for driving the display panel 100. The timing controller can receive image signals and control signals from an external host system or the like. The image signals can include a plurality of grayscale data. The control signals can include, for example, a vertical synchronization signal, a horizontal synchronization signal, a data enable signal, and the like.

The display device can also include additional elements related to additional functions other than the function of operating the pixels. For example, the display device can include additional elements that provide a touch detection function, a user certification function (e.g., fingerprint recognition), a multi-level pressure detection function, a tactile feedback function, and the like. The above-mentioned additional elements can be positioned in the non-display area NA, and/or the display area AA, and/or an external circuit connected to a connection interface.

The display device according to aspects of the present disclosure can be included in or applied to other electronic devices such as a TV, a mobile terminal such as a smart phone, a navigation system, a computer, a gaming system, an extended reality (XR) system, etc.

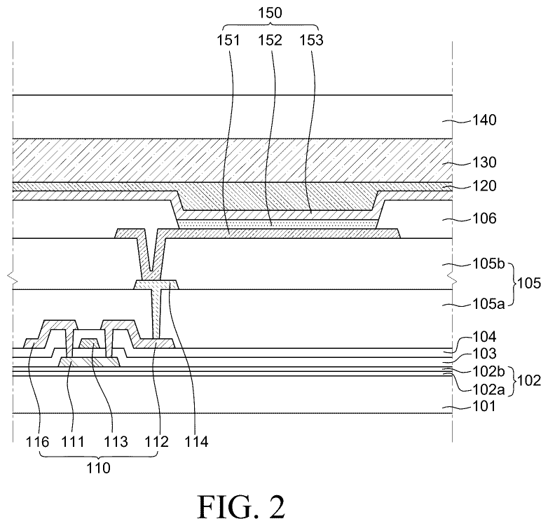

FIG. 2 is a cross-sectional view of the subpixel of the display device according to the first embodiment of the present disclosure. Each subpixel of the display panel 100 in this and other embodiments can have the configuration of the subpixel shown in FIG. 2, but can have other configurations.

With reference to FIG. 2, in the display panel of the display device of the first embodiment of the present disclosure, a driving element 110 can be disposed on a first substrate 101. Further, a planarization layer 105 can be disposed on the driving element 110.

In addition, an organic light-emitting element 150, which is electrically connected to the driving element 110, can be disposed on the planarization layer 105, and a protective layer 120 can be disposed on the organic light-emitting element 150, thereby suppressing any penetration of oxygen and moisture into the organic light-emitting element 150.

A filling member 130 and a second substrate 140 can be sequentially disposed on the protective layer 120.

However, the present disclosure is not limited to the above-mentioned stacked structure. For example, the filling member 130 can be a bonding member.

The first substrate 101 can be a glass or plastic substrate. The first substrate 101 can be flexible (e.g., bendable, rollable, etc.).

In case that the substrate 101 is a plastic substrate, a polyimide-based material or a polycarbonate-based material is used, such that the substrate can have flexibility. Polyimide is widely used for the plastic substrate because polyimide is a material that can be applied to a high-temperature process and used for coating.

A buffer layer 102 can be disposed on the first substrate 101.

The buffer layer 102 is a layer for protecting various types of electrodes and lines from impurities such as alkaline ions leaking from the first substrate 101 or lower layers. The buffer layer 102 can have a multilayer structure including a first buffer layer 102a and a second buffer layer 102b. However, the present disclosure is not limited thereto. For instance, the buffer layer 102 can have a single-layer structure. The buffer layer 102 can be made of silicon oxide (SiOx) or silicon nitride (SiNx) or can be configured as a multilayer including silicon oxide (SiOx) or silicon nitride (SiNx).

The buffer layer 102 can delay the diffusion of moisture and/or oxygen which may penetrate into the first substrate 101. In addition, the buffer layer 102 can include a multi-buffer and/or an active buffer. The active buffer can serve to protect an active layer 111 of the driving element 110, and the active layer 111 can be made of a semiconductor. The active buffer can serve to block various types of defects which may be introduced from the first substrate 101. The active buffer can be made of amorphous silicon (a-Si) or the like.

As a non-limiting example, the driving element 110 can be configured such that the active layer 111, an insulation layer 103, a gate electrode 113, a gate insulation layer 104, a source electrode 116, and a drain electrode 112 can be sequentially disposed. The driving element 110 can be electrically connected to the organic light-emitting element 150 through a connection electrode 114 and transmit an electric current or signal from the driving element 110 to the organic light-emitting element 150. For instance, the driving element 110 can be a thin film transistor of various types, and depending on the type of the driving element 110, the locations of the source electrode 116 and the drain electrode 112 can be switched or varied.

The active layer 111 can be disposed on the buffer layer 102. The active layer 111 can be made of polysilicon (p-Si). In this case, a predetermined area of the active layer 111 can be doped with impurities. In addition, the active layer 111 can be made of amorphous silicon (a-Si) or an organic semiconductor material such as pentacene. In addition, the active layer 111 can be made of an oxide.

The insulation layer 103 can be disposed on the active layer 111. The insulation layer 103 can be made of an insulating inorganic material such as silicon oxide (SiOx) or silicon nitride (SiNx). In addition, the insulation layer 103 can be made of an insulating organic material or the like.

The gate electrode 113 can be disposed on the insulation layer 103. The gate electrode 113 can be made of various electrically conductive materials, for example, magnesium (Mg), aluminum (Al), nickel (Ni), chromium (Cr), molybdenum (Mo), tungsten (W), gold (Au), or an alloy thereof.

The gate insulation layer 104 can be disposed on the gate electrode 113. For example, the gate insulation layer 104 can be made of an insulating inorganic material such as silicon oxide (SiOx) or silicon nitride (SiNx). In addition, the gate insulation layer 104 can be made of an insulating organic material.

In an example, contact holes, through which source and drain areas are exposed, can be formed by selectively removing portions of the insulation layer 103 and the gate insulation layer 104, where the source and drain electrodes 116, 112 can be disposed in such contact holes. The source electrode 116 and the drain electrode 112 can each have a single-layer or multilayer structure disposed on the gate insulation layer 104 and can be made of a material for an electrode. If necessary, an additional protective layer (e.g., passivation layer) made of an inorganic insulating material can be formed to cover the source electrode 116 and the drain electrode 112.

The planarization layer 105 can be disposed on the driving element 110 configured as described above.

The planarization layer 105 can have a multilayer structure including at least two layers. For example, the planarization layer 105 can include a first planarization layer 105a and a second planarization layer 105b. The first planarization layer 105a can be disposed to cover the driving element 110 while the drain electrode 112 of the driving element 110 are partially exposed.

The planarization layer 105 can extend to the non-display area NA of the display panel 100.

The planarization layer 105 can be an overcoat layer. However, the present disclosure is not limited thereto.

In addition, the connection electrode 114 can be disposed on the first planarization layer 105a and electrically connect the driving element 110 to the organic light-emitting element 150. In addition, various metal layers can be disposed on the first planarization layer 105a and serve as electrodes and electric wires such as data lines or signal lines.

In addition, the second planarization layer 105b can be disposed on the first planarization layer 105a and the connection electrode 114. The configuration in which the planarization layer 105 of the first embodiment of the present disclosure is provided as two layers is based on the fact that the number of various types of signal lines increases as the display device has a high resolution. The additional layer is provided since it may be difficult to dispose all the lines on a single layer while ensuring minimum intervals. The addition of the additional layer (e.g., the second planarization layer 105b) can provide a margin for disposing lines, which further facilitates the disposition design of lines/electrodes. Further, in case that a dielectric material is used for the planarization layer 105 having a multilayer structure, the planarization layer 105 can serve to create capacitance between the metal layers.

The second planarization layer 105b can be formed such that a part of the connection electrode 114 is exposed through the second planarization layer 105b. As such, the drain electrode 112 of the driving element 110 and an anode 151 of the organic light-emitting element 150 can be electrically connected to each other by the connection electrode 114.

The organic light-emitting element 150 can be configured by sequentially disposing the anode 151, one or a plurality of organic layers 152, and a cathode 153. For example, the organic light-emitting element 150 can include the anode 151 formed on the planarization layer 105, the organic layer 152 formed on the anode 151, and the cathode 153 formed on the organic layer 152.

The display device in all embodiments of the present disclosure can be implemented as a top emission type or a bottom emission type. In the case of the top emission type, a reflective layer made of an opaque conductive material with high reflectance, for example, silver (Ag), aluminum (Al), gold (Au), molybdenum (Mo), tungsten (W), chromium (Cr), or an alloy thereof can be additionally disposed below the anode 151 so that light, which is emitted from the organic layer 152, is reflected by the anode 151 and propagates upward, i.e., in a direction toward the cathode 153 at the upper side. In contrast, in the case of the bottom emission type, the anode 151 can be made of only a transparent electrically conductive material such as indium tin oxide (ITO), indium zinc oxide (IZO), or indium gallium zinc oxide (IGZO). Hereinafter, the description will be made on the assumption that the display device of the present disclosure is the top emission type.

A bank 106 can be provided on the planarization layer 105 and disposed in the remaining area excluding the light-emitting area. For example, the bank 106 has a bank hole through which the anode 151 corresponding to the light-emitting area is exposed. The bank 106 can be made of an inorganic insulating material such as silicon nitride (SiNx) or silicon oxide (SiOx) or made of an organic insulating material such as BCB, acrylic resin, or imide-based resin.

The bank 106 can extend to the non-display area NA of the display panel 100.

The organic layer 152 of the organic light-emitting element 150 can be disposed on the anode 151 exposed by the bank 106. The organic layer 152 can include a light-emitting layer, an electron injection layer, an electron transport layer, a hole transport layer, a hole injection layer, and the like, but can have other structures/configurations.

The organic layer 152 can extend to the non-display area NA of the display panel 100. In the non-display area NA, the organic layer 152 can be disposed on the planarization layer 105.

The cathode 153 of the organic light-emitting element 150 can be disposed on the organic layer 152.

In the case of the top emission type, the cathode 153 can include a transparent electrically conductive material. For example, the cathode 153 can be made of indium tin oxide (ITO), indium zinc oxide (IZO), indium gallium zinc oxide (IGZO), or the like. In the case of the bottom emission type, the cathode 153 can include any one selected from a group consisting of metallic materials such as gold (Au), silver (Ag), aluminum (Al), molybdenum (Mo), magnesium (Mg), palladium (Pd), and copper (Cu) or an alloy thereof. Alternatively, the cathode 153 can be configured by stacking a layer made of a transparent electrically conductive material such as indium tin oxide (ITO), indium zinc oxide (IZO), or indium gallium zinc oxide (IGZO) and a layer made of metallic materials such as gold (Au), silver (Ag) aluminum (Al), molybdenum (Mo), magnesium (Mg), palladium (Pd), and copper (Cu) or an alloy thereof. However, the present disclosure is not limited thereto.

The cathode 153 can extend to the non-display area NA. In the non-display area NA, the cathode 153 can be disposed to cover the organic layer 152. For example, the organic layer 152 can be disposed to be spaced apart from an end of the cathode 153 at a predetermined distance. However, the present disclosure is not limited thereto. For example, the cathode 153 can be disposed to be spaced apart from an end of the planarization layer 105 at a predetermined distance. However, the present disclosure is not limited thereto.

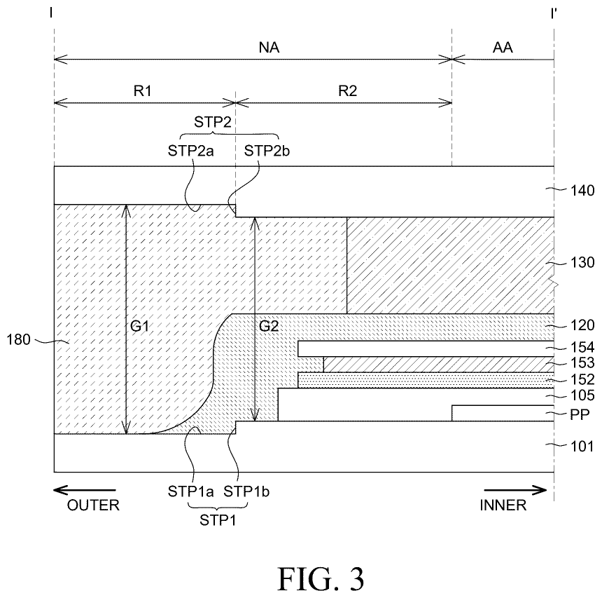

Meanwhile, a capping layer (e.g., see a capping layer 154 in FIG. 3) can also be disposed on the organic light-emitting element 150. The capping layer can be made of a material with a large refractive index and a high optical absorption rate to reduce an irregular reflection of external light.

Further, the protective layer 120 can be disposed on the cathode 153. The protective layer 120 can be an inorganic layer. In this case, the protective layer 120 can be made of silicon oxide (SiOx) or silicon nitride (SiNx) or configured as a multilayer including silicon oxide (SiOx) or silicon nitride (SiNx). For example, the protective layer 120 can extend to the non-display area NA. The protective layer 120 can be disposed to cover the cathode 153 and the planarization layer 105.

Meanwhile, an optical layer can be additionally disposed between the cathode 153 and the protective layer 120. The optical layer can uniformly transmit light emitted from the display panel 100 to the outside without reducing the brightness of the display device. The optical layer can absorb or reflect external light to improve display quality. For example, the optical layer can be a polarizing plate. However, the present disclosure is not limited thereto.

The filling member 130 and the second substrate 140 can be disposed on the protective layer 120. The filling member 130 can be disposed to surround the protective layer 120.

The filling member 130, together with the protective layer 120 and the second substrate 140, can protect the organic light-emitting element 150 of a pixel part from outside moisture, oxygen, impact, and the like. The filling member 130 can further include a moisture absorbent material. The moisture absorbent material can include particles having hygroscopicity. The moisture absorbent material can absorb moisture, oxygen, and the like from the outside, thereby minimizing a degree to which moisture and oxygen may penetrate into the pixel part or the organic light-emitting element 150. However, the present disclosure is not limited thereto.

The filling member 130 can include a filler. The filler can be made of a transparent material so that brightness does not deteriorate while light emitted from the organic light-emitting element 150 passes through the second substrate 140. For example, the filler can be made of epoxy or olefin and can include talc, calcium oxide (CaO), barium oxide (BaO), zeolite (zeolite), silicon oxide (SiO), and the like.

The second substrate 140 can be disposed on the filling member 130. The second substrate 140, together with the filling member 130, can protect the organic light-emitting element 150 of the pixel part. The second substrate 140 can protect the organic light-emitting element 150 from outside moisture, oxygen, impact, and the like. The second substrate 140 can be flexible and can be made with the same or similar material as the first substrate 101, but can also be made with a different material.

FIG. 3 is a cross-sectional view taken along line I-I′ in FIG. 1.

Particularly, FIG. 3 shows a cross-sectional view taken along line I-I′ in the display panel 100 of FIG. 1 according to the first embodiment of the present disclosure. Hereinafter, a description of a configuration identical to the configuration described with reference to FIGS. 1 and 2 will be omitted or may be briefly provided, so that the description below will be focused on difference(s) therebetween.

With reference to FIG. 3, the display device of the first embodiment of the present disclosure can include the first substrate 101, the second substrate 140, a pixel part PP, the planarization layer 105, the organic layer 152, the cathode 153, the capping layer 154, the protective layer 120, the filling member 130, and a dam 180.

According to the first embodiment of the present disclosure, the display device can be divided into the display area AA and the non-display area NA. The non-display area NA can surround the display area AA entirely (e.g., see FIG. 1) or only in part(s). The pixel part PP is disposed in the display area AA, but the pixel part PP is not disposed in the non-display area NA.

The non-display area NA can include a first area R1 and a second area R2. The first area R1 can be edge areas of the first and second substrates 101 and 140. The second area R2 can be an area positioned inside the first area R1. The first area R1 can surround the second area R2 entirely (e.g., see FIG. 1) or only in part(s). The second area R2 extends directly to the first area R1 in the non-display area NA. As a variation, the non-display area NA can have other area(s).

In the first area R1 of the non-display area NA, a first gap G1 can be formed between the first substrate 101 and the second substrate 140. In the second area R2, a second gap G2 can be formed between the first substrate 101 and the second substrate 140. The first gap G1 can be formed to be larger than the second gap G2. In other words, the gap defined at an outer portion of the non-display area NA can be formed to be larger than the gap defined at an inner portion of the non-display area NA.

In the first area R1, an inner surface (e.g., surface directly contacting the dam 180) of at least one of the first substrate 101 and the second substrate 140 can be partially etched. At least one of the first substrate 101 and the second substrate 140 is etched in the first area R1, such that the first gap G1 can be formed to be larger than the second gap G2 (i.e., G1>G2).

At least one of the first substrate 101 and the second substrate 140 can have a thickness in the first area R1 that is smaller than a thickness in the second area R2. For example, the thickness of the first substrate 101 in the first area R1 can be smaller than the thickness of the first substrate 101 in the second area R2. In addition or in the alternative, the thickness of the second substrate 140 in the first area R1 can be smaller than the thickness of the second substrate 140 in the second area R2.

Stepped portions STP1 and STP2 can be formed on the first substrate 101 and/or the second substrate 140 and disposed between the first area R1 and the second area R2. The stepped portions STP1 and STP2 can include stepped bottom surfaces and stepped wall surfaces. For example, the stepped portions STP1 and STP2 can be formed in stepped shapes.

For example, the first substrate 101 can include a first stepped portion STP1 disposed between the first area R1 and the second area R2, e.g., at a boundary area between the first and second areas R1 and R2. In addition, the second substrate 140 can include a second stepped portion STP2 disposed between the first area R1 and the second area R2, e.g., at a boundary area between the first and second areas R1 and R2. A value made by adding a sum of a value of a height of the first stepped portion STP1 and a value of a height of the second stepped portion STP2 to a value of the second gap G2 can be equal to or substantially equal to a value of the first gap G1.

In this example, the first stepped portion STP1 can include a first stepped bottom surface STP1a and a first stepped wall surface STP1b. The second stepped portion STP2 can include a second stepped bottom surface STP2a and a second stepped wall surface STP2b. The stepped wall surfaces STP1b and STP2b can also be referred to as stepped sidewall surfaces. The stepped bottom surfaces STP1a and STP2a can also be referred to as stepped top surfaces or stepped inner surfaces depending on the orientation of the display panel.

The display device can include the dam 180 provided in the non-display area NA to ensure reliability while suppressing moisture penetration.

In addition, the dam 180 can be provided at the edge area of the first substrate 101 and disposed between the first substrate 101 and the second substrate 140. The dam 180 can reinforce a bonding force between the first substrate 101 and the second substrate 140 and block moisture.

The dam 180 can be disposed in the non-display area NA at or near an outer periphery of the display area AA. For example, the dam 180 can be disposed on a plane to surround entirely all the pixel parts PP of the display panel (e.g., see FIG. 1). The dam 180, together with the filling member 130, can join and seal the first substrate 101 and the second substrate 140.

As such, the first and/or second stepped portion STP1 and STP2 and its configuration shown in FIG. 3 can be applied and present in all the non-display area NA of the display panel 100 extending along the entire outer periphery area of the display panel 100. For instance, the stepped portions STP1 and STP2 surround completely the entire display area AA of the display panel 100.

According to the first embodiment of the present disclosure described above, at least one of the first substrate 101 and the second substrate 140 can include the first stepped portion STP1 and/or the second stepped portion STP2. Due to the formation of the stepped portions STP1 and STP2, contact areas between the dam 180 and the first substrate 101 and/or the second substrate 140 can increase, which strengthens the sealing/bonding aspect between the first and second substrates 101 and 140. As a result, the reliability of the display device can be improved and the lifespan of the display device can be lengthened.

Specifically, the dam 180 can be disposed in the first area R1. The dam 180 can be disposed in the entire first area R1. The dam 180 can be disposed between the first substrate 101 and the second substrate 140 and disposed to fill at least one of the first stepped portion STP1 and the second stepped portion STP2.

The dam 180 can be disposed in a part of the second area R2. For example, the dam 180 can be disposed in a part of the second area R2, while the filling member 130 can be disposed to fill in the remaining part of the second area R2. The dam 180 can be positioned at an outer portion of the second area R2, and the filling member 130 can be disposed at an inner portion of the second area R2.

The planarization layer 105, the organic layer 152, the cathode 153, the capping layer 154, and/or the protective layer 120 can be sequentially disposed in the second area R2. In the second area R2, the filling member 130 and the dam 180 can be disposed above the protective layer 120.

According to the configuration shown in FIG. 3, the display device with improved characteristics can be provided. For instance, there is always a need to reduce the bezel of a display device. However, when the bezel is narrowed, a distance between an end of a dam and an end of an organic layer can be shortened, and the dam is also thinned such that a moisture-penetration preventing distance is shortened, which is not desirable. To address this limitation, according to the first embodiment of the present disclosure, the stepped portions STP1 and STP2 are formed on the first substrate 101 and/or the second substrate 140. As such, it is possible to ensure there is a sufficient moisture-penetration preventing distance even though the bezel may be narrowed. Therefore, it is possible to significantly reduce a bezel width of the display device by grinding an edge of the display device. For example, according to the first embodiment of the present disclosure, the first substrate 101, the second substrate 140, and the dam 180 can be grinded so that a side surface of the first substrate 101, a side surface of the second substrate 140, and a side surface of the dam 180 are consistent with one another, e.g., they are aligned with each other.

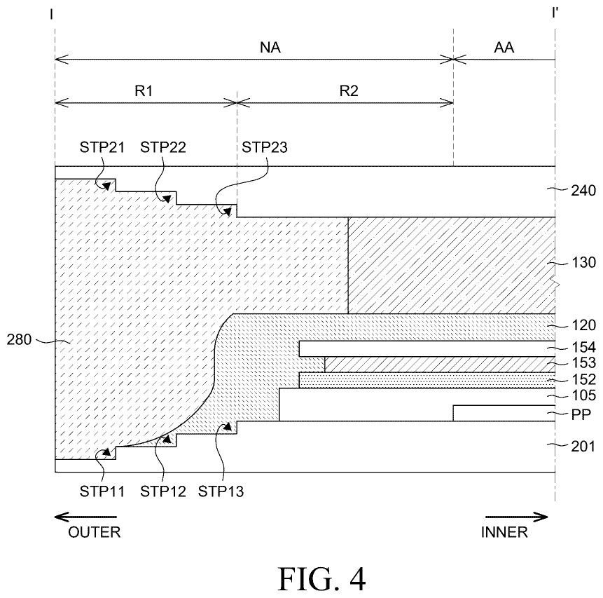

FIG. 4 is a cross-sectional view of a display device according to a second embodiment of the present disclosure. Particularly, FIG. 4 shows another example of a cross-sectional view taken along line I-I′ in FIG. 1 according to the second embodiment of the present disclosure.

The second embodiment of the present disclosure illustrated in FIG. 4 is substantially identical in configuration to the above-mentioned first embodiment illustrated in FIGS. 1 to 3, except that inner surfaces of first and second substrates 201 and 240 have a plurality of stepped portions STP11, STP12, STP13, STP21, STP22, and STP23. Therefore, repeated descriptions of the identical components will be omitted or may be briefly provided. The same reference numerals are used for the same components. For instance, the components in FIG. 4, which are denoted by the same reference numerals as the components shown in FIGS. 1 to 3, have already been described above with reference to FIGS. 1 to 3, and such description can be referred to herein.

With reference to FIG. 4, the display device of the second embodiment of the present disclosure can include the first substrate 201, the second substrate 240, the pixel part PP, the planarization layer 105, the organic layer 152, the cathode 153, the capping layer 154, the protective layer 120, the filling member 130, and/or a dam 280.

According to the second embodiment of the present disclosure, at least one of the first substrate 201 and the second substrate 240 can include the plurality of stepped portions STP11, STP12, STP13, STP21, STP22, and STP23 provided on the inner surface(s) thereof.

For example, the first substrate 201 can include at least two among the plurality of first stepped portions STP11, STP12, and STP13. For example, the second substrate 240 can include at least two among the plurality of second stepped portions STP21, STP22, and STP23. In addition, for example, the first substrate 201 can include the plurality of first stepped portions STP11, STP12, and STP13, and at the same time, the second substrate 240 can include the plurality of second stepped portions STP21, STP22, and STP23.

More specifically, the plurality of first stepped portions STP11, STP12, and STP13 can include a first-first stepped portion STP11, a first-second stepped portion STP12, and a first-third stepped portion STP13. The first-first stepped portion STP11 may be also referred to as a first portion of the first stepped portion, e.g. a first step of the first stepped portion. Similarly, the first-second stepped portion STP12 may be referred to as a second portion or second step of the first stepped portion. The first-third stepped portion STP13 may be referred to as a third portion or third step of the first stepped portion. In addition, the plurality of second stepped portions STP21, STP22, and STP23 can include a second-first stepped portion STP21, a second-second stepped portion STP22, and a second-third stepped portion STP23. The second-first stepped portion STP21 may be also referred to as a first portion of the second stepped portion, e.g. a first step of the second stepped portion. Similarly, the second-second stepped portion STP22 may be referred to as a second portion or second step of the second stepped portion. The second-third stepped portion STP23 may be referred to as a third portion or third step of the second stepped portion. However, the number of stepped portions is not limited thereto, and can be equal to or greater than two (2) for each of at least one of the first and second substrates 201 and 240.

Here, the first stepped portions STP11, STP12, and STP13 or the second stepped portions STP21, STP22, and STP23 can be formed by etching. However, the present disclosure is not limited thereto.

Since the plurality of first stepped portions STP11, STP12, and STP13 and/or the plurality of second stepped portions STP21, STP22, and STP23 are formed, a thickness of each of at least one of the first substrate 201 and the second substrate 240 increases in a direction from the outer portion of the display panel toward the inner portion of the display panel.

For example, in the first area R1, the first substrate 201 can be thickened in the direction from the outer portion of the display panel toward the inner portion of the display panel. In addition, for example, in the first area R1, the second substrate 240 can be thickened in the direction from the outer portion of the display panel toward the inner portion of the display panel. Therefore, in the first area R1, a gap between the first substrate 201 and the second substrate 240 can be narrowed or decreased in the direction from the outer portion of the display panel toward the inner portion of the display panel.

Since the plurality of stepped portions STP11, STP12, STP13, STP21, STP22, and STP23 are formed on the inner surface of at least one of the first substrate 201 and the second substrate 240, a height difference between the stepped bottom surfaces of the adjacent stepped portions (e.g., the stepped bottom surfaces of the first-first stepped portion STP11 and the first-second stepped portion STP12, the stepped bottom surfaces of the first-second stepped portion STP12 and the first-third stepped portion STP13, the stepped bottom surfaces of the second-first stepped portion STP21 and the second-second stepped portion STP22, and the stepped bottom surfaces of the second-second stepped portion STP22 and the second-third stepped portion STP23) can be reduced or decrease.

In one example, the heights of the stepped portions STP11-STP13 and/or the stepped portions STP21-STP23 can be the same. In another example, the heights of the stepped portions STP11-STP13 can decrease in the direction from the outer portion of the display panel toward the inner portion of the display panel; the heights of the stepped portions STP21-STP23 can decrease in the direction from the outer portion of the display panel toward the inner portion of the display panel; or both.

The protective layer 120 can cover all or some of the stepped portions STP11-13, and have a tapered end in the first area R1 of the non-display area NA.

The configuration of the stepped portions in FIG. 4 can be present and applied in all the non-display area NA of the display panel extending along the entire outer periphery area of the display panel. For instance, the stepped portions STP21-23 and/or STP11-13 of FIG. 4 surround completely the entire display area AA of the display panel 100 in the second embodiment of the present disclosure.

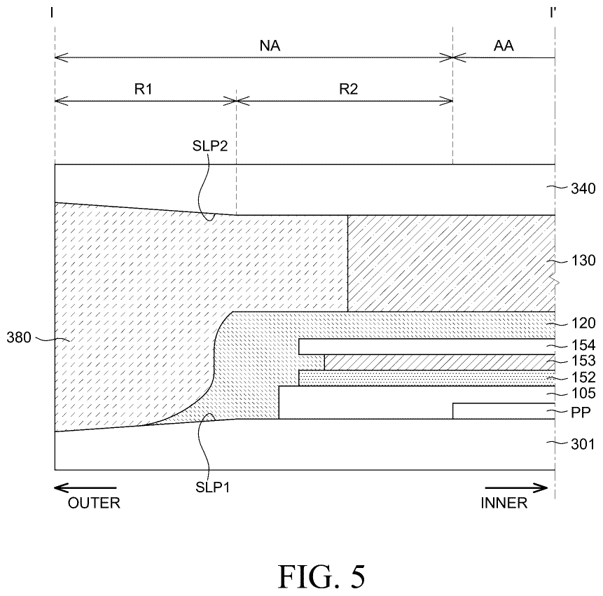

FIG. 5 is a cross-sectional view of a display device according to a third embodiment of the present disclosure. Particularly, FIG. 5 shows another example of a cross-sectional view taken along line I-I′ in FIG. 1 according to the third embodiment of the present disclosure.

The third embodiment of the present disclosure illustrated in FIG. 5 is substantially identical in configuration to the above-mentioned first embodiment illustrated in FIGS. 1 to 3 (or the second embodiment of FIG. 4), except that inner surfaces of first and second substrates 301 and 340 have inclined surfaces SLP1 and SLP2. Therefore, repeated descriptions of the identical components will be omitted or may be briefly provided. The same reference numerals are used for the same components. For instance, the components in FIG. 5, which are denoted by the same reference numerals as the components shown in FIGS. 1 to 4, have already been described above with reference to FIGS. 1 to 4, and such description can be referred to herein.

With reference to FIG. 5, the display device of the third embodiment of the present disclosure can include the first substrate 301, the second substrate 340, the pixel part PP, the planarization layer 105, the organic layer 152, the cathode 153, the capping layer 154, the protective layer 120, the filling member 130, and/or a dam 380.

In the first area R1, a first gap can be formed between the first substrate 301 and the second substrate 340. In the second area R2, a second gap can be formed between the first substrate 301 and the second substrate 340. The first gap can be formed to be larger than the second gap. In other words, the gap defined at an outer area of the non-display area NA can be formed to be larger than the gap defined at an inner area of the non-display area NA.

In the first area R1, an inner surface of at least one of the first substrate 301 and the second substrate 340 can be partially etched. At least one of the first substrate 301 and the second substrate 340 is etched in the first area R1, such that the first gap can be formed to be larger than the second gap.

In the first area R1, at least one of the first substrate 301 and the second substrate 340 can be etched to have the corresponding inclined surface SLP1 and/or SLP2. In other words, each of at least one of the first substrate 301 and the second substrate 340 can have the corresponding inclined surface SLP1 or SLP2. For example, the first substrate 301 can have the first inclined surface SLP1 in the first area R1. For example, the second substrate 340 can have the second inclined surface SLP2 in the first area R1. In addition, for example, the first substrate 301 can have the first inclined surface SLP1, and at the same time, the second substrate 340 can have the second inclined surface SLP2.

In addition, in the first area R1, a thickness of the first substrate 301 can decrease in a direction from the inner portion of the display panel toward the outer portion of the display panel. The thickness of the first substrate 301 can continuously decrease outward to define the first inclined surface SLP1. In the first area R1, a thickness of the second substrate 340 can decrease in the direction from the inner portion of the display panel toward the outer portion of the display panel. The thickness of the second substrate 340 can continuously decrease outward to define the second inclined surface SLP2. Therefore, the first gap between the first substrate 301 and the second substrate 340, which is measured in the first area R1, can be generally larger than the second gap between the first substrate 301 and the second substrate 340 that is measured in the second area R2. In this case, the first gap can be an average value of various gaps measured in the first area R1.

As a variation, the inclined surfaces SLP1 and SLP2 can have the same single inclination angle, or can be different inclination angles. The inclination angle can be an acute angle less than 90 degrees. In still another example, each of the inclined surfaces SLP1 and SLP2 can be broken into multiple inclined surfaces that are connected to each other.

Because the inclined surfaces SLP1 and SLP2 are formed on the substrates (e.g., the first substrate 301 and/or the second substrate 340), contact areas between the dam 380 and the substrates 301 and 340 can increase, which strengthens the sealing/bonding aspect between the first and second substrates 301 and 340. As a result, the reliability of the display device can be improved and the lifespan of the display device can be lengthened.

The configuration of the inclined surfaces in FIG. 5 can be present and applied in all the non-display area NA of the display panel extending along the entire outer periphery area of the display panel. For instance, the inclined surfaces SLP1 and/or SLP2 of FIG. 5 surround completely the entire display area AA of the display panel 100 in the third embodiment of the present disclosure.

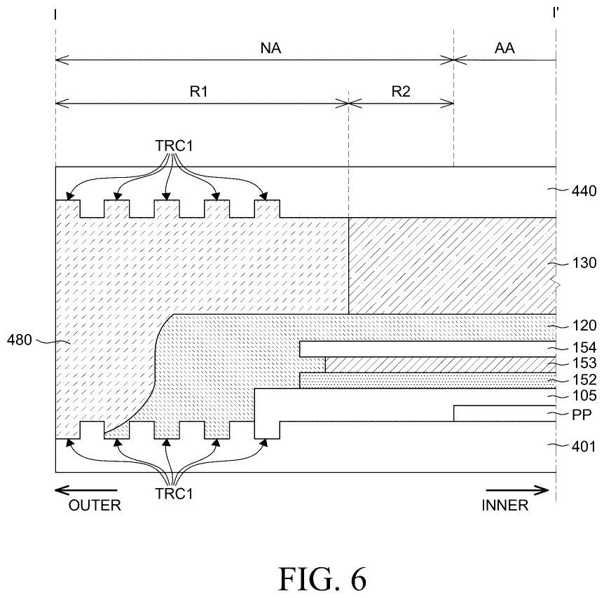

FIG. 6 is a cross-sectional view of a display device according to a fourth embodiment of the present disclosure. Particularly, FIG. 6 shows another example of a cross-sectional view taken along line I-I′ in FIG. 1 according to the fourth embodiment of the present disclosure.

The fourth embodiment of the present disclosure illustrated in FIG. 6 is substantially identical in configuration to the above-mentioned first embodiment illustrated in FIGS. 1 to 3 (or the second or third embodiment), except that inner surfaces of first and second substrates 401 and 440 have trenches TRC1 and TRC2. Therefore, repeated descriptions of the identical components will be omitted or may be briefly provided. The same reference numerals are used for the same components. For instance, the components in FIG. 6, which are denoted by the same reference numerals as the components shown in FIGS. 1 to 5, have already been described above with reference to FIGS. 1 to 5 and such description can be referred to herein.

With reference to FIG. 6, the display device of the fourth embodiment of the present disclosure can include the first substrate 401, the second substrate 440, the pixel part PP, the planarization layer 105, the organic layer 152, the cathode 153, the capping layer 154, the protective layer 120, the filling member 130, and/or a dam 480.

According to the fourth embodiment, the first substrate 401 and/or the second substrate 440 can include the plurality of trenches TRC1 and/or TRC2. For example, the first substrate 401 can include the plurality of first trenches TRC1. In addition, for example, the second substrate 440 can include the plurality of second trenches TRC2. In addition, for example, the first substrate 401 can include the plurality of first trenches TRC1, and at the same time the second substrate 440 can include the plurality of second trenches TRC2.

For example, the first trench TRC1 can be formed on a front surface (e.g., inner surface) of the first substrate 401. The second trench TRC2 can be formed on a rear surface (e.g., inner surface) of the second substrate 440. The first trench TRC1 and the second trench TRC2 can be formed to face each other. The number of first trenches TRC1 and the number of second trenches TRC2 can be equal to each other. However, the present disclosure is not limited thereto and thus, such numbers can be different from each other. In this example, both the front surface and the rear surface can be the inner surfaces, but other variations are possible.

The non-display area NA can include the first area R1 and the second area R2. For example, the plurality of first trenches TRC1 can be formed in the first area R1. The plurality of first trenches TRC1 is not formed in the second area R2. For example, the plurality of second trenches TRC2 can be formed in the first area R1. The plurality of second trenches TRC2 is not formed in the second area R2. The plurality of trenches (e.g., the first trench TRC1 and the second trench TRC2) can be formed by etching. However, the present disclosure is not limited thereto.

The plurality of first trenches TRC1 are formed on the inner surface of the first substrate 401, which can increase a contact area between the first substrate 401 and the dam 480 in the first area R1. The plurality of second trenches TRC2 is formed on the inner surface of the second substrate 440, which can increase a contact area between the second substrate 440 and the dam 480 in the first area R1, which strengthens sealing/bonding aspect between the first and second substrates 401 and 440.

According to the fourth embodiment, the plurality of first trenches TRC1 and/or the plurality of second trenches TRC2 can be formed in the entire first area R1. However, the present disclosure is not limited thereto.

As a variation, the plurality of first trenches TRC1 and/or the plurality of second trenches TRC2 can be formed only in part(s) of the first area R1. For example, the plurality of first trenches TRC1 can be formed in only a part or the entirety of the first area R1. For example, the plurality of second trenches TRC2 can be formed in only a part or the entirety of the first area R1. In addition, for example, both the plurality of first trenches TRC1 and the plurality of second trenches TRC2 can be formed in only a part or the entirety of the first area R1.

Meanwhile, in case that the first and second trenches TRC1 and TRC2 are formed, the first gap between the first substrate 401 and the second substrate 440, which is measured in the first area R1, can be larger than the second gap between the first substrate 401 and the second substrate 440 that is measured in the second area R2. In this case, the first gap can be an average value of various gaps measured in the first area R1.

In an example, the first trenches TRC1 can be aligned with or substantially aligned with the second trenches TRC2, such that the first and second trenches TRC1 and TRC2 have indentations that mirror each other in an aligned manner. In another example, the first and second trenches TRC1 and TRC2 may be misaligned, such that the indentations of the first trenches TRC1 are mirror the protrusions of the second trenches TRC2.

In still another example, each of the first and second trenches TRC1 and TRC2 can have the same shape and/or sizes, or can have varying shapes and/or sizes. For instance, the first trenches TRAC1 can have different shapes and/or sizes with each other, and/or the second trenches TRAC2 can have different shapes and/or sizes with each other. In another example, each of one or more trenches among the first trenches TRAC1 can have a different (changing) shape and/or size for that trench, as it is disposed along the periphery area of the display panel, and/or each of one or more trenches among the second trenches TRAC2 can have a different (changing) shape and/or size for that trench, as it is disposed along the periphery area of the display panel.

The configuration of the trenches in FIG. 6 can be present and applied in all the non-display area NA of the display panel extending along the entire outer periphery area of the display panel. For instance, the trenches TRC1 and/or TRC2 of FIG. 6 surround completely the entire display area AA of the display panel 100 in the fourth embodiment of the present disclosure.

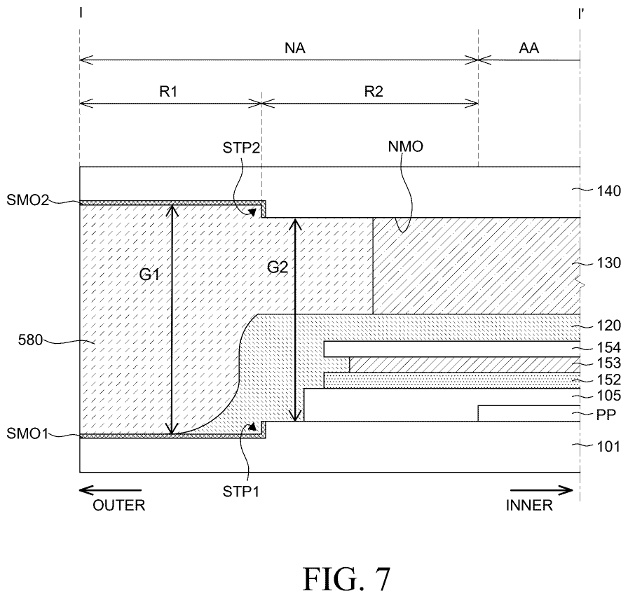

FIG. 7 is a cross-sectional view of a display device according to a fifth embodiment of the present disclosure. Particularly, FIG. 7 shows another example of a cross-sectional view taken along line I-I′ in FIG. 1 according to the fifth embodiment of the present disclosure.

The fifth embodiment of the present disclosure illustrated in FIG. 7 is substantially identical in configuration to the above-mentioned first embodiment illustrated in FIGS. 1 to 3, except that modified portions SMO1 and SMO2 are provided in the stepped portions STP1 and STP2 of the first and second substrates 101 and 140. Therefore, repeated descriptions of the identical components will be omitted or may be briefly provided. The same reference numerals are used for the same components. For instance, the components in FIG. 7, which are denoted by the same reference numerals as the components shown in FIGS. 1 to 6, have already been described above with reference to FIGS. 1 to 6, and such description can be referred to herein.

With reference to FIG. 7, the display device of the fifth embodiment of the present disclosure can include the first substrate 101, the second substrate 140, the pixel part PP, the planarization layer 105, the organic layer 152, the cathode 153, the capping layer 154, the protective layer 120, the filling member 130, and/or a dam 580.

As described above, the non-display area NA can include the first area R1 and the second area R2. The first area R1 can be an edge area of the substrate. The second area R2 can be an area positioned at or adjacent to an inner area of the first area R1. The first area R1 can surround the second area R2 entirely or in parts.

In the first area R1 of the non-display area NA, at least one of the first substrate 101 and the second substrate 140 can include the modified portions SMO1 and/or SMO2 in the stepped portions STP1 and/or STP2. For example, the first substrate 101 can include the first modified portion SMO1 at the first stepped portion STP1. For example, the second substrate 140 can include the second modified portion SMO2 at the second stepped portion STP2. In addition, for example, the first substrate 101 can include the first modified portion SMO1 at the first stepped portion STP1, and at the same time, the second substrate 140 can include the second modified portion SMO2 at the second stepped portion STP2.

The modified portions SMO1 and/or SMO2 can be formed by performing a surface modification treatment on the first substrate 101 and/or the second substrate 140. The surface modification treatment can include a chemical surface modification treatment or physical surface modification treatment. The chemical surface modification treatment can include silane coupling agent (R1-Si—(OR2)₃) treatment, amine (—NH₂) treatment, epoxy (—CH₂—CH—) treatment, methacrylate treatment, alkoxy group treatment, and hydroxyl group treatment. However, the present disclosure is not limited thereto. The physical surface modification treatment can include a plasma treatment. However, the present disclosure is not limited thereto.

In this regard, the chemical structures or physical structures of the inner surface of the first substrate 101 and/or the inner surface of the second substrate 140 are adjusted by the chemical surface modification treatment or physical surface modification treatment, such that the modified portions SMO1 and SMO2 can be formed. The modified portions SMO1 and SMO2 can improve the bonding force, compatibility, water resistance, and the like of the first and second substrates 101 and 140. Specifically, the modified portions SMO1 and SMO2 can reinforce the bonding force of the first and second substrates 101 and 140 with the dam 580, which can strengthen the bonding/sealing aspect among the first and second substrates 101 and 140 and the dam 580.

For example, the modified portions SMO1 and SMO2 can each have a higher surface roughness than a non-modified portion NMO of the inner surfaces of the first and second substrates 101 and 140.

The modified portions SMO1 and SMO2 can be positioned in the first area R1.

The non-modified portion NMO can be positioned in the second area R2 and/or the display area AA. For example, the non-modified portion NMO can be positioned both in the display area AA and the second area R2, but not in the first area R1. In another example, the non-modified portion NMO can be positioned in the display area AA.

The modified portions SMO1 and SMO2 having a high surface roughness are formed in the stepped portions STP1 and STP2 of the first substrate 101 and/or the second substrate 140, which can increase a surface area or contact area of the first and/or second substrate in the first area R1. Therefore, in the first area R1, the bonding forces between the dam 480 and the first substrate 101 and/or the second substrate 140 can be significantly improved, which strengthen the sealing/bonding aspect among the first and second substrates 101 and 140 and the dam 580. As a result, the reliability of the display device can be improved and the lifespan of the display device can be lengthened.

In the first area R1, the first gap G1 can be formed between the first substrate 101 and the second substrate 140. In the second area R2, the second gap G2 can be formed between the first substrate 101 and the second substrate 140. The first gap G1 can be formed to be larger than the second gap G2. In other words, the gap defined at an outer portion of the non-display area NA can be formed to be larger than the gap defined at an inner portion of the non-display area NA.

In the first area R1, the inner surface of at least one of the first substrate 101 and the second substrate 140 can be partially etched. At least one of the first substrate 101 and the second substrate 140 is etched in the first area R1, such that the first gap G1 can be formed to be larger than the second gap G2.

Each of at least one of the first substrate 101 and the second substrate 140 can have a thickness in the first area R1 that is smaller than a thickness in the second area R2. For example, the thickness of the first substrate 101 in the first area R1 can be smaller than the thickness of the first substrate 101 in the second area R2. For example, the thickness of the second substrate 140 in the first area R1 can be smaller than the thickness of the second substrate 140 in the second area R2.

The stepped portions STP1 and/or STP2 can be formed on the first substrate 101 and/or the second substrate 140 and disposed between or around the boundary between the first area R1 and the second area R2. The stepped portions STP1 and STP2 can include the stepped bottom surfaces and the stepped wall surfaces (e.g., see FIG. 3). For example, the stepped portions STP1 and STP2 can be formed in stepped shapes. In detail, the first substrate 101 can include the first stepped portion STP1 between the first area R1 and the second area R2. In addition, the second substrate 140 can include the second stepped portion STP2 between the first area R1 and the second area R2. A value made by adding a sum of a value of a height of the first stepped portion STP1 and a value of a height of the second stepped portion STP2 to a value of the second gap G2 can be equal to or substantially equal to a value of the first gap G1. The first stepped portion STP1 can include the first stepped bottom surface and the first stepped wall surface. The second stepped portion STP2 can include the second stepped bottom surface and the second stepped wall surface.

Meanwhile, as a variation according to the fifth embodiment of the present disclosure, the stepped portions STP1 and STP2 may not be formed on the first substrate 101 and/or the second substrate 140. In this case, only the modified portions SMO1 and SMO2 can be formed in the first area R1. In detail, in the first area R1 of the first substrate 101 and/or the second substrate 140, only the modified portions SMO1 and SMO2 can be formed while the stepped portions STP1 and STP2 are not formed in the first area R1.

The configuration of the modified portions SMO1 and SMO2 in FIG. 7 can be present and applied in all the non-display area NA of the display panel extending along the entire outer periphery area of the display panel. For instance, the modified portions SMO1 and/or SMO2 with or without the stepped portions STP1 and/or STP2 of FIG. 7 surround completely the entire display area AA of the display panel 100 in the fifth embodiment of the present disclosure.

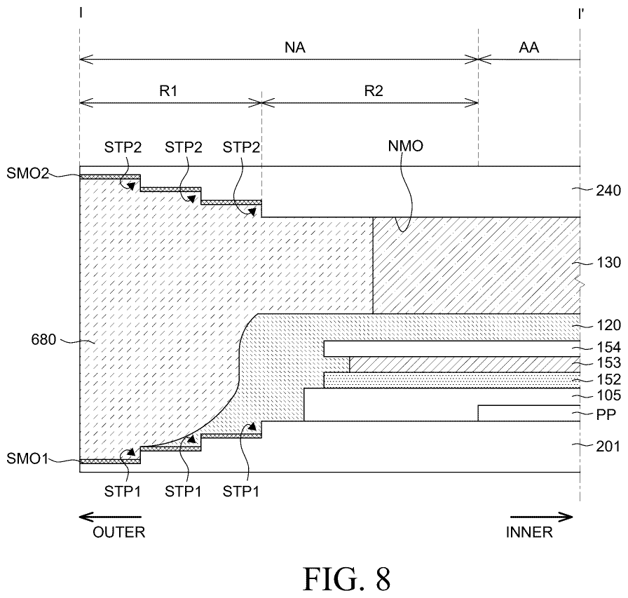

FIG. 8 is a cross-sectional view of a display device according to a sixth embodiment of the present disclosure. Particularly, FIG. 8 shows another example of a cross-sectional view taken along line I-I′ in FIG. 1 according to the sixth embodiment of the present disclosure.

The sixth embodiment of the present disclosure illustrated in FIG. 8 is substantially identical in configuration to the above-mentioned second embodiment illustrated in FIG. 4, except that the modified portions SMO1 and SMO2 are provided in the plurality of stepped portions STP1 and STP2 of the first and second substrates 201 and 240. Therefore, repeated descriptions of the identical components will be omitted or may be briefly provided. The same reference numerals are used for the same components. For instance, the components in FIG. 8, which are denoted by the same reference numerals as the components shown in FIGS. 1 to 7, have already been described above with reference to FIGS. 1 to 7, and such description can be referred to herein.

With reference to FIG. 8, the display device of the sixth embodiment of the present disclosure can include the first substrate 201, the second substrate 240, the pixel part PP, the planarization layer 105, the organic layer 152, the cathode 153, the capping layer 154, the protective layer 120, the filling member 130, and/or a dam 680.

According to the sixth embodiment, the first substrate 201 can include the plurality of first stepped portions STP1. In addition, the second substrate 240 can include the plurality of second stepped portions STP2. The first modified portions SMO1 can be formed on the stepped bottom surfaces and/or the stepped wall surfaces of at least some of the plurality of first stepped portions STP1. In addition, the second modified portions SMO2 can be formed on the stepped bottom surfaces and/or the stepped wall surfaces of at least some of the plurality of second stepped portions STP2.

The configuration of the modified portions SMO1 and/or SMO2 at one or more of the stepped portions STP1, STP2 in FIG. 8 can be present and applied in all the non-display area NA of the display panel extending along the entire outer periphery area of the display panel. For instance, the modified portions SMO1 and/or SMO2 at one or more of the stepped portions STP1, STP2 of FIG. 8 can surround completely the entire display area AA of the display panel 100 in the sixth embodiment of the present disclosure.

The following advantages and features can be obtained according to various aspects of the present disclosure.

The inner surfaces of the first and second substrates in the first area (or outer area) of the non-display area (where the first and second substrates and the dam are bonded) can have pattern(s) that increase the surface/contact areas of such inner surfaces.

Further, these pattern(s) can be located to generally correspond to an area where the protective layer 120 begins to taper into the first area R1 of the non-display area NA.

Due to the formation of such patterns including at least one of the stepped portions, inclined surfaces, modified portions, trenches, etc. discussed above, contact or bonding areas among the first and second substrates and the dam are increased, which in turn strengthens the sealing/bonding among the first and second substrates and the dam in the non-display area. As a result, the reliability of the display device can be improved and the lifespan of the display device can be lengthened.

Further, due to such configuration discussed above, it is possible to ensure there is a sufficient moisture-penetration preventing distance even though the bezel may be narrowed. Therefore, it is possible to significantly reduce a bezel width of the display device by grinding an edge of the display device.

The aspects of the present disclosure can also be described as follows:

According to an aspect of the present disclosure, there is provided a display device. The display device includes a first substrate divided into a display area and a non-display area, a second substrate disposed above the first substrate and a dam provided in the non-display area, disposed between the first substrate and the second substrate, and configured to bond the first substrate and the second substrate, the non-display area can include a first area and a second area, and a first gap between the first substrate and the second substrate in the first area can be larger than a second gap between the first substrate and the second substrate in the second area.

The dam can be disposed in the first area.

The dam can be disposed to extend to a part of the second area.

The first area can be positioned outward of the second area.

A filling member can be positioned in a part of the second area, and the filling member can be disposed between the first substrate and the second substrate.

The first substrate can have a first stepped portion provided on an inner surface thereof, and the second substrate can have a second stepped portion provided on an inner surface thereof.

The first stepped portion and the second stepped portion can be disposed on a boundary between the first area and the second area, and the first gap can be disposed to be larger than the second gap by the first stepped portion and the second stepped portion.

At least one of the first substrate and the second substrate in the first area can include a modified portion provided on the first stepped portion or the second stepped portion, at least one of the first substrate and the second substrate in the second area can include a non-modified portion provided on an inner surface thereof, and the modified portion can have higher surface roughness than the non-modified portion.

The first substrate can have a first inclined surface provided on an inner surface thereof, the second substrate can have a second inclined surface provided on an inner surface thereof, and the first gap can be an average value of different gaps in the first area.

The first substrate can have a thickness that decreases in a direction from the inside toward the outside, and the thickness of the first substrate can decrease to define the first inclined surface, and the second substrate can have a thickness that decreases in the direction from the inside toward the outside, and the thickness of the second substrate can decrease to define the second inclined surface.

The first substrate can have a first trench provided on an inner surface thereof, the second substrate can have a second trench provided on an inner surface thereof, and the first gap can be an average value of different gaps in the first area.

According to another aspect of the present disclosure, there is provided a display device. The display device includes a first substrate divided into a display area and a non-display area, a second substrate disposed above the first substrate and a dam provided in the non-display area, disposed between the first substrate and the second substrate, and configured to bond the first substrate and the second substrate, the non-display area can include a first area and a second area, at least one of the first substrate and the second substrate in the first area can include a modified portion provided on an inner surface thereof, at least one of the first substrate and the second substrate in the second area can include a non-modified portion provided on an inner surface thereof, and the modified portion can have higher surface roughness than the non-modified portion.

The dam can be disposed in the first area.

The dam can be disposed to extend to a part of the second area.

The first area can be positioned outward of the second area.

A filling member can be positioned in a part of the second area, and the filling member can be disposed between the first substrate and the second substrate.

The first substrate can have a first stepped portion provided on an inner surface thereof, and the second substrate can have a second stepped portion provided on an inner surface thereof.

The modified portion can comprise a first modified portion and a second modified portion, the first modified portion can be disposed on the first substrate, and the second modified portion can be disposed on the second substrate.

The first modified portion can be disposed on the first stepped portion, and the second modified portion can be disposed on the second stepped portion.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device comprising:
a first substrate divided into a display area configured to display an image and a non-display area adjacent to the display area;
a second substrate disposed on the first substrate; and
a dam provided in the non-display area, disposed between the first substrate and the second substrate, and configured to bond the first substrate and the second substrate,
wherein the non-display area includes a first area and a second area, and
wherein a first gap between the first substrate and the second substrate in the first area of the non-display area is larger than a second gap between the first substrate and the second substrate in the second area of the non-display area.

2. The display device of claim 1, wherein the dam is disposed in the first area of the non-display area, and further extends into a part of the second area of the non-display area.

3. The display device of claim 1, wherein the first area is located at an outer portion of the non-display area and contacts the second area located at an inner portion of the non-display area.

4. The display device of claim 1, wherein the first substrate has at least one first stepped portion provided at an inner surface of the first substrate, and
wherein the second substrate has at least one second stepped portion provided at an inner surface of the second substrate.

5. The display device of claim 4, wherein the at least one first stepped portion and the at least one second stepped portion are disposed around a boundary between the first area and the second area in the non-display area, so that the first gap is larger than the second gap due to the first stepped portion and the second stepped portion.

6. The display device of claim 4, wherein at least one of the first substrate and the second substrate in the first area of the non-display area includes a modified portion provided at the first stepped portion or the second stepped portion,
wherein at least one of the first substrate and the second substrate in the second area of the non-display area includes a non-modified portion provided at an inner surface thereof, and
wherein the modified portion has a higher surface roughness than the non-modified portion.

7. The display device of claim 1, wherein the first substrate has a first inclined surface provided at an inner surface of the first substrate,
wherein the second substrate has a second inclined surface provided at an inner surface of the second substrate, and
wherein the first gap between the first substrate and the second substrate in the first area of the non-display area is determined to be an average value of different gaps in the first area, and is larger than the second gap between the first substrate and the second substrate in the second area of the non-display area.

8. The display device of claim 7, wherein the first substrate has a thickness that decreases in a direction from an inner portion of the non-display area toward an outer portion of the non-display area, and the thickness of the first substrate decreases to define the first inclined surface, and/or
wherein the second substrate has a thickness that decreases in the direction from the inner portion of the non-display area toward the outer portion of the non-display area, and the thickness of the second substrate decreases to define the second inclined surface.

9. The display device of claim 1, wherein the first substrate has at least one first trench provided on an inner surface of the first substrate,
wherein the second substrate has at least one second trench provided on an inner surface of the second substrate, and
wherein the first gap between the first substrate and the second substrate in the first area of the non-display area is determined to be an average value of different gaps in the first area, and is larger than the second gap between the first substrate and the second substrate in the second area of the non-display area.

10. A display device comprising:
a first substrate divided into a display area and a non-display area surrounding the display area;
a second substrate disposed on the first substrate; and
a dam provided in the non-display area, disposed between the first substrate and the second substrate, and configured to bond the first substrate and the second substrate,
wherein the non-display area includes a first area and a second area,
wherein at least one of the first substrate and the second substrate in the first area of the non-display area includes a modified portion provided at an inner surface thereof in the first area,
wherein at least one of the first substrate and the second substrate in the second area of the non-display area includes a non-modified portion provided at an inner surface thereof in the second area, and
wherein the modified portion has a higher surface roughness than the non-modified portion.

11. The display device of claim 10, wherein the dam is disposed in the first area of the non-display area, and further extends into a part of the second area of the non-display area.

12. The display device of claim 10, wherein the first area is located at an outer portion of the non-display area and contacts the second area located at an inner portion of the non-display area.

13. The display device of claim 10, wherein the first substrate further includes at least one first stepped portion provided at the inner surface of the first substrate in the first area of the non-display area, and
wherein the second substrate further includes at least one second stepped portion provided at the inner surface of the second substrate in the first area of the non-display area.

14. The display device of claim 13, wherein the modified portion comprises a first modified portion and a second modified portion,
wherein the first modified portion is disposed at the inner surface of the first substrate in the first area of the non-display area, and
wherein the second modified portion is disposed at the inner surface of the second substrate in the first area of the non-display area.

15. The display device of claim 14, wherein the first modified portion is disposed at the first stepped portion in the first area of the non-display area, and
wherein the second modified portion is disposed at the second stepped portion in the first area of the non-display area.

16. A display device comprising:
a first substrate and a second substrate facing each other, and including a display area and a non-display area adjacent to the display area;
a plurality of pixels disposed between the first and second substrates in the display area, and configured to display an image; and
a dam disposed between the first and second substrates along the non-display area, and surrounding the display area,
wherein an inner surface of each of at least one of the first and second substrates in the non-display area includes at least one pattern that increases a bonding surface area to improve bonding between at least one of the first and second substrates and the dam in the non-display area.

17. The display device of claim 16, wherein the at least one pattern in the non-display area includes a single stepped portion, a plurality of stepped portions, an inclined surface, or trenches.

18. The display device of claim 17, wherein when the at least one pattern in the non-display area includes the single stepped portion or the plurality of stepped portions, the at least one pattern further includes a modified portion provided at a surface of the single stepped portion or the plurality of stepped portions in the non-display area, and
wherein the modified portion has a surface roughness that is higher than a non-modified portion in the non-display area.

19. The display device of claim 16, wherein the inner surface of each of the first and second substrates in the non-display area includes the at least one pattern, and
wherein the at least one pattern on the first substrate mirrors the at least one pattern on the second substrate.

20. The display device of claim 16, further comprising:
a protective layer covering the plurality of pixels in the display area, and extending into the non-display area,
wherein the at least one pattern in the non-display area is located to correspond to an area where the protective layer begins to taper toward an outer portion of the non-display area.

21. The display device of claim 16, wherein a distance between the inner surface of the first substrate and the inner surface of the second substrate increases in a direction from an inner portion of the non-display area toward an outer portion of the non-display area.
